(19) United States
(12) Patent Application Publication
(10) Pub. No.: US 2022/0120609 A1
(43) Pub. Date: Apr. 21, 2022

(54) ELECTRONIC DEVICE

(71) Applicant: VISUAL SENSING TECHNOLOGY CO., LTD., Hsinchu City (TW)

(72) Inventor: Wei-Hung Hsu, Taoyuan City (TW)

(21) Appl. No.: 17/198,289

(22) Filed: Mar. 11, 2021

Related U.S. Application Data
(60) Provisional application No. 63/093,290, filed on Oct. 18, 2020.

(30) Foreign Application Priority Data
Dec. 2, 2020 (TW) 109142387

(51) Int. Cl. G01J 1/04; G01J 1/42

(52) U.S. Cl. CPC G01J 1/0429; G01J 1/0418; G01J 1/4228; G01J 1/4204

(57) ABSTRACT

An electronic device is disclosed. The electronic device includes a display, a first optical sensor, a second optical sensor and a first circular polarizer. The first circular polarizer includes a first quarter waveplate, a first linear polarizer, a second quarter waveplate and a second linear polarizer. The first quarter waveplate is disposed between the display and the first optical sensor, and the first linear polarizer is disposed between the first quarter waveplate and the first optical sensor. The second quarter waveplate is disposed between the display and the second optical sensor, and the second linear polarizer is disposed between the second quarter waveplate and the second optical sensor.

### CROSS REFERENCE TO RELATED APPLICATIONS

This patent application claims the benefit of U.S. provisional application No. 63/093,290, filed Oct. 18, 2020, and the entire contents of which are incorporated herein by reference.

### BACKGROUND OF THE INVENTION

### 1. Field of the Invention

The present invention relates to an electronic device, and more particularly to an electronic device with an ambient light sensor.

### 2. Description of the Prior Art

Currently, electronic devices with borderless full-screen appearance (such as smart phones, etc.) have become the main trend. In order to achieve the requirement of borderless full-screen, all components (such as an ambient light sensor, etc.) must be integrated and disposed below the screen. Under this condition, the sensors receive the ambient light and the light emitted by the screen simultaneously, and the ambient light detected by the sensors is interfered by the change of the image or the brightness on the screen, thereby making the electronic device unable to accurately adjust the screen brightness.

### SUMMARY OF THE INVENTION

One of the technical problems to be solved in the present invention is that the ambient light detected by the sensor is interfered by the change of the image or the brightness on the screen of the electronic device.

To solve the technical problem described above, the present invention provides an electronic device including a display, a first optical sensor, a second optical sensor and a first circular polarizer. The display includes a first side and a second side opposite to the first side. The first optical sensor and the second optical sensor are disposed on the first side of the display. The first circular polarizer is disposed on the first side of the display. The first circular polarizer includes a first quarter waveplate, a first linear polarizer, a second quarter waveplate and a second linear polarizer. The first quarter waveplate is disposed between the display and the first optical sensor, and the first linear polarizer is disposed between the first quarter waveplate and the first optical sensor. The second quarter waveplate is disposed between the display and the second optical sensor, and the second linear polarizer is disposed between the second quarter waveplate and the second optical sensor.

In the present invention, the intensity of the ambient light can be accurately obtained and the interference of the light emitted by the display can be eliminated through the first circular polarizer and the dual channel sensor (such as the first optical sensor and the second optical sensor). For example, the ambient light sensors (such as the first optical sensor and the second optical sensor) in the electronic device can detect the change of the ambient light without being affected by the change of the image or the brightness of the display, and thus the electronic device can adjust the screen brightness more precisely.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a sectional-view schematic diagram of an electronic device of a first embodiment according to the present invention.

FIG. 2 is a schematic diagram of a first quarter waveplate, a first linear polarizer and a first optical sensor of the first embodiment according to the present invention.

FIG. 3 is a schematic diagram of a second quarter waveplate, a second linear polarizer and a second optical sensor of the first embodiment according to the present invention.

FIG. 4 is a schematic diagram of a first quarter waveplate, a first linear polarizer and a first optical sensor of a second embodiment according to the present invention.

FIG. 5 is a schematic diagram of a second quarter waveplate, a second linear polarizer and a second optical sensor of the second embodiment according to the present invention.

### DETAILED DESCRIPTION

The present invention may be understood by reference to the following detailed description, taken in conjunction with the drawings as described below. It is noted that, for purposes of illustrative clarity and being easily understood by the readers, various drawings of the present invention show a portion of the electronic device, and certain components in various drawings may not be drawn to scale. In addition, the number and dimension of each component shown in drawings are only illustrative and are not intended to limit the scope of the present disclosure.

It should be understood that when a component or layer is referred to as being “on”, “disposed on” or “connected to” another component or layer, it may be directly on or directly connected to the other component or layer, or intervening components or layers may be presented (indirect condition). In contrast, when a component is referred to as being “directly on”, “directly disposed on” or “directly connected to” another component or layer, there are no intervening components or layers present.

A direction X and a direction Z are labeled in the following drawings. The direction Z may be perpendicular to the upper surface or the lower surface of the substrate 100 or the cover layer 112, the direction X may be parallel to the upper surface or the lower surface of the substrate 100 or the cover layer 112, and the direction Z may be perpendicular to the direction X. The spatial relationship of the structure can be described according to the direction X and the direction Z in the following drawings.

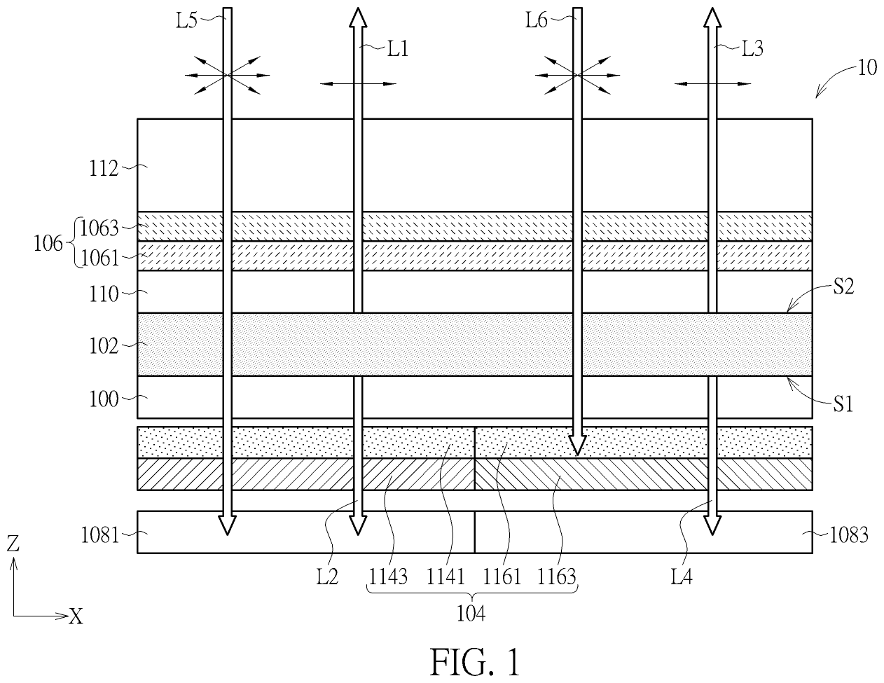

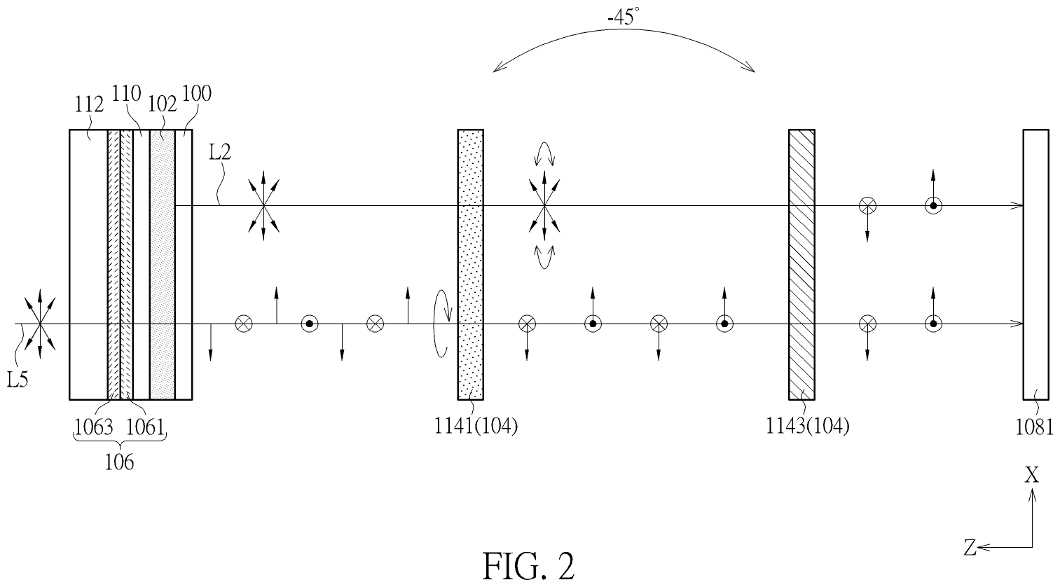

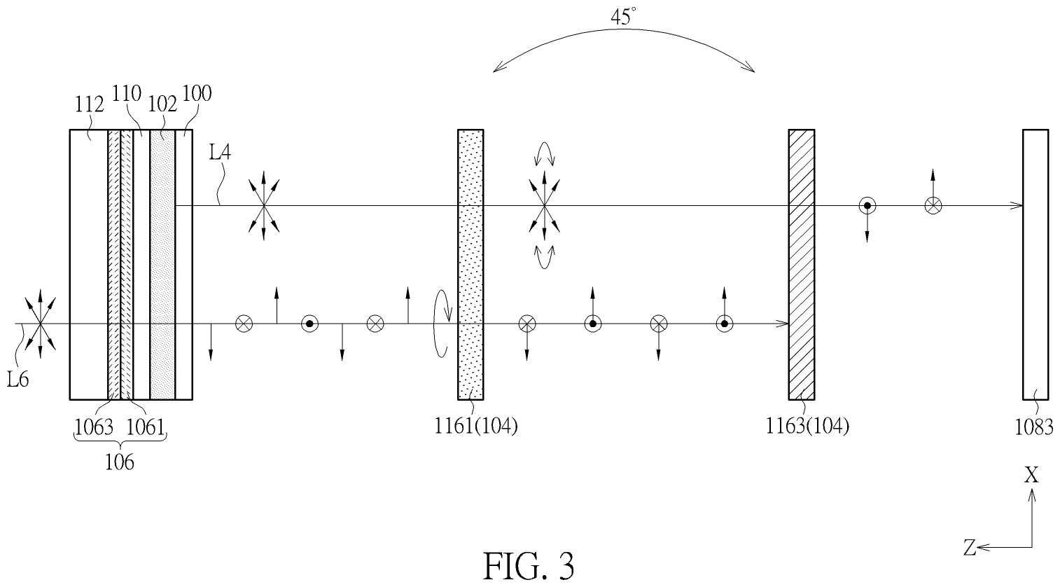

Please refer to FIG. 1 to FIG. 3. FIG. 1 is a sectional-view schematic diagram of an electronic device of a first embodiment according to the present invention. FIG. 2 is a schematic diagram of a first quarter waveplate, a first linear polarizer and a first optical sensor of the first embodiment according to the present invention. FIG. 3 is a schematic diagram of a second quarter waveplate, a second linear polarizer and a second optical sensor of the first embodiment according to the present invention. As shown in FIG. 1, the electronic device 10 of this embodiment may include a substrate 100, a display 102, a circular polarizer 104 (also referred to as a first circular polarizer), a circular polarizer 106 (also referred to as a second circular polarizer), an optical sensor 1081 (also referred to as a first optical sensor) and an optical sensor 1082 (also referred to as a second optical sensor).

The substrate 100 may include a rigid substrate, a flexible substrate or the combination of the above, but not limited herein. The material of the substrate 100 may include glass, quartz, metal, ceramic, organic polymer, combinations of the above or other suitable materials, but not limited herein. When the material of the substrate 100 is organic polymer, it may include polyethylene terephthalate (PET), polyimide (PI), polycarbonate (PC) or combinations of the above, but not limited herein.

Various electronic components may be disposed on the substrate 100, such as integrated circuits (IC), thin film transistors, conductive pads, wires or combinations of the above, but not limited herein. In addition, insulating layers or protective layers may be disposed on the substrate 100. In order to make the drawings simpler or clearer, the electronic components or the insulating layers described above are omitted in the drawings of the present invention.

The display 102 may be disposed on the substrate 100, and the display 102 may include a self-luminous display panel or a non-self-luminous display panel, but not limited herein. For example, the display 102 may include an organic light emitting diode display panel, an inorganic light emitting diode display panel, a quantum dot display panel, a liquid crystal display panel, a cholesteric liquid crystal display panel, an electrophoretic display panel, etc. In the display 102 of this embodiment, an active matrix organic light emitting diode (AMOLED) display panel is taken as an example, but not limited herein.

In addition, the electronic device 10 of this embodiment may include an encapsulation layer 110 disposed on the display 102. Therefore, the display 102 of this embodiment is disposed between the encapsulation layer 110 and the substrate 100, but not limited herein. The encapsulation layer 110 may include organic or inorganic insulating materials, and the encapsulation layer 110 may be transparent, but not limited herein.

As shown in FIG. 1, the display 102 includes a first side S1 and a second side S2 opposite to the first side S1, and the second side S2 may be opposite to the first side S1 in the direction Z. The substrate 100, the circular polarizer 104, the optical sensor 1081 and the optical sensor 1083 may be disposed on the first side S1 of the display 102. The substrate 100 may be disposed between the circular polarizer 104 and the display 102, and the circular polarizer 104 may be disposed between the display 102 and the optical sensor (such as the optical sensor 1081 or the optical sensor 1083).

As shown in FIG. 1, the encapsulation layer 110 and the circular polarizer 106 may be disposed on the second side S2 of the display 102, and the encapsulation layer 110 may be disposed between the circular polarizer 106 and the display 102. In addition, the electronic device 10 may include a cover layer 112 disposed on the second side S2 of the disp1ay 102, and the circular polarizer 106 may be disposed between the cover layer 112 and the display 102. The cover layer 112 can protect the display 102, and the cover layer 112 of this embodiment may be a transparent rigid substrate, such as a cover glass, but not limited herein.

The circular polarizer 106 may include a quarter waveplate 1061 (also referred to as a third quarter waveplate) and a linear polarizer 1063 (also referred to as a third linear polarizer). The linear polarizer 1063 is disposed on the quarter waveplate 1061, and the quarter waveplate 1061 is disposed between the linear polarizer 1063 and the display 102.

The circular polarizer 104 may include one or more quarter waveplates 1141 (also referred to as “first quarter waveplate”), one or more linear polarizers 1143 (also referred to as “first linear polarizer”), one or more quarter waveplates 1161 (also referred to as “second quarter waveplate”) and one or more linear polarizers 1163 (also referred to as “second linear polarizer”). The quarter waveplate 1141 is disposed on the linear polarizer 1143, and the quarter waveplate 1161 is disposed on the linear polarizer 1163. Therefore, as shown in FIG. 1, the positional relationship between the quarter waveplate 1061 and the linear polarizer 1063 in the direction Z is reversed from the positional relationship between the quarter waveplate 1141 and the linear polarizer 1143 (or the quarter waveplate 1161 and the linear polarizer 1163).

The quarter waveplate 1061, the quarter waveplate 1141 or the quarter waveplate 1161 may be a light transmitting layer constructed by optical anisotropic lattice materials or anisotropic sub-wavelength structures, but not limited herein. The linear polarizer 1063, the linear polarizer 1143 or the linear polarizer 1163 may be constructed by polymer materials or metal wire grids, but not limited herein. The quarter waveplate 1141 has an optical axis, the linear polarizer 1143 has a polarization direction, and an included angle between the optical axis of the quarter waveplate 1141 and the polarization direction of the linear polarizer 1143 is −45 degrees. On the other hand, the quarter waveplate 1161 has an optical axis, the linear polarizer 1163 has a polarization direction, and an included angle between the optical axis of the quarter waveplate 1161 and the polarization direction of the linear polarizer 1163 is 45 degrees. The optical axis of the quarter waveplate 1141 and the optical axis of the quarter waveplate 1161 can have the same direction, but not limited herein. In addition, the included angle between the polarization direction of the linear polarizer 1143 and the polarization direction of the linear polarizer 1163 can be 90 degrees, but not limited herein.

The optical sensor 1081 may be disposed corresponding to the quarter waveplate 1141 and the linear polarizer 1143 in the direction Z, and the optical sensor 1083 may be disposed corresponding to the quarter waveplate 1161 and the linear polarizer 1163 in the direction Z. As shown in FIG. 1, the quarter waveplate 1141 is disposed between the display 102 and the optical sensor 1081, and the linear polarizer 1143 is disposed between the quarter waveplate 1141 and the optical sensor 1081. In addition, the quarter waveplate 1161 is disposed between the display 102 and the optical sensor 1083, and the linear polarizer 1163 is disposed between the quarter waveplate 1161 and the optical sensor 1083.

As shown in FIG. 1, the quarter waveplate 1141 may be parallel to the optical sensor 1081, and an area of the quarter waveplate 1141 may be the same as an area of the optical sensor 1081, but not limited herein. In addition, the quarter waveplate 1161 may be parallel to the optical sensor 1083, and an area of the quarter waveplate 1161 may be the same as an area of the optical sensor 1083, but not limited herein.

As shown in FIG. 1, the linear polarizer 1143 may be parallel to the optical sensor 1081, and an area of the linear polarizer 1143 may be the same as the area of the optical sensor 1081, but not limited herein. In addition, the linear polarizer 1163 may be parallel to the optical sensor 1083, and an area of the linear polarizer 1163 may be the same as the area of the optical sensor 1083, but not limited herein.

The optical sensor (such as the optical sensor 1081 or the optical sensor 1083) may include photoelectric conversion components such as a complementary metal oxide semiconductor (CMOS) sensor, a photodiode (PD), etc. One optical sensor 1081 and one optical sensor 1083 may form a dual channel sensor, and the electronic device 10 may include one or more dual channel sensors. For example, the optical sensor 1081 is served as one of the channels, and the optical sensor 1083 is served as the other one of the channels. In FIG. 1, the optical sensor 1081 and the optical sensor 1083 are disposed adjacent to each other, but the present invention is not limited herein. In other embodiments, the optical sensor 1081 and the optical sensor 1083 may be disposed separately.

According to the structure of the electronic device 10 described above, the effects provided by the present invention are described below. As shown in FIG. 1, among the light emitted by the display 102, the light L1 and the light L3 may be emitted from the display 102 toward the cover layer 112, and the light L2 and the light L4 may be emitted from the display 102 toward the optical sensor 1081 or the optical sensor 1083. In addition, the ambient light L5 and the ambient light L6 may enter the electronic device 10 from the cover layer 112, and advance toward the optical sensor 1081 or the optical sensor 1083. In FIG. 1, the directions of the light L1 and the light L3 are parallel to each other and identical to the direction Z, and the directions of the light L2, the light L4, the ambient light L5 and the ambient light L6 are parallel to each other and opposite to the direction Z, but the directions of the light are not limited herein.

As shown in FIG. 1, the ambient light L5 and the ambient light L6 are unpolarized before entering the electronic device 10. For example, the circular polarizer 106 of this embodiment can be a right-handed circular polarizer, but not limited herein. As shown in FIG. 2 and FIG. 3, when the ambient light L5 and the ambient light L6 enter the electronic device 10, the ambient light L5 and the ambient light L6 pass through the quarter waveplate 1061 and the linear polarizer 1063 of the circular polarizer 106 in sequence, and the ambient light L5 and the ambient light L6 are right-handed polarized. The ambient light L5 and the ambient light L6 may be reflected in the electronic device 10 after the ambient light L5 and the ambient light L6 enter the electronic device 10. The circular polarizer 106 can prevent the reflected light from passing through the cover layer 112 to the outside of the electronic device 10, so as to maintain the display quality of the image of the electronic device 10.

In this embodiment, since the included angle between the linear polarizer 1143 and the quarter waveplate 1141 is −45 degrees, the linear polarizer 1143 and the quarter waveplate 1141 also form a right-handed circular polarizer. As shown in FIG. 2, the ambient light L5 may pass through the quarter waveplate 1141 and the linear polarizer 1143 of the circular polarizer 104 in sequence. First, a portion of the polarization of the ambient light L5 perpendicular to the optical axis of the quarter waveplate 1141 is retarded by the influence of the crystalline structure of the quarter waveplate 1141 (e.g., the moving distance can be retarded by a length of a quarter of the wavelength) after the ambient light L5 passes through the quarter waveplate 1141, and thus the right-handed polarized ambient light L5 can become linearly polarized. Then, since the polarization direction of the ambient light L5 passing through the quarter waveplate 1141 may be parallel to the polarization direction of the linear polarizer 1143, the ambient light L5 may fully pass through the linear polarizer 1143. Therefore, the ambient light L5 is able to pass through the quarter waveplate 1141 and the linear polarizer 1143, and the ambient light L5 can be detected by the optical sensor 1081.

As shown in FIG. 3, in this embodiment, since the included angle between the linear polarizer 1163 and the quarter waveplate 1161 is 45 degrees, the linear polarizer 1163 and the quarter waveplate 1161 may form a left-handed circular polarizer. First, a portion of the polarization of the ambient light L6 perpendicular to the optical axis of the quarter waveplate 1161 is retarded by the influence of the crystalline structure of the quarter waveplate 1161 (e.g., the moving distance can be retarded by a length of a quarter of the wavelength) after the ambient light L6 passes through the quarter waveplate 1161, and thus the right-handed polarized ambient light L6 can become linearly polarized. However, since the polarization direction of the ambient light L6 passing through the quarter waveplate 1161 is perpendicular to the polarization direction of the linear polarizer 1163, the ambient light L6 is not able to pass through the linear polarizer 1163. Therefore, the optical sensor 1083 is not able to detect the ambient light L6.

As shown in FIG. 2 and FIG. 3, the light L2 and the light L4 emitted from the display 102 are unpolarized. Therefore, the light L2 and the light L4 are still unpolarized after passing through the quarter waveplate 1141 and the quarter waveplate 1161. Then, the polarization direction of a portion of the light L2 is parallel to the polarization direction of the linear polarizer 1143, and this portion of the light L2 can pass through the linear polarizer 1143. However, the polarization direction of another portion of the light L2 is perpendicular to the polarization direction of the linear polarizer 1143, and this portion of the light L2 is not able to pass through the linear polarizer 1143.

Similarly, the polarization direction of a portion of the light L4 is parallel to the polarization direction of the linear polarizer 1163, and this portion of the light L4 can pass through the linear polarizer 1163. However, the polarization direction of another portion of the light L4 is perpendicular to the polarization direction of the linear polarizer 1163, and this portion of the light L4 is not able to pass through the linear polarizer 1163.

In addition, the light L2 or the light L4 may have a first intensity before passing through the quarter waveplate 1141 or the quarter waveplate 1161. The light L2 may have a second intensity after passing through the quarter waveplate 1141 and the linear polarizer 1143, or the light L4 may have a second intensity after passing through the quarter waveplate 1161 and the linear polarizer 1163, and the second intensity can be half of the first intensity.

Thus, the optical sensor 1081 can detect the light L2 from the display 102 with the second intensity and the ambient light L5 with the full intensity, and the optical sensor 1083 can detect the light L4 from the display 102 with the second intensity but is not able to detect the ambient light L6. Then, the full intensity of the ambient light L5 can be obtained by subtracting the values obtained by the optical sensor 1081 and the optical sensor 1083 through the calculation element. The calculation element may include a processor or an integrated circuit, but not limited herein.

Therefore, the full intensity of the ambient light L5 can be obtained and the interference of the light L2 and the light L4 emitted by the display 102 can be eliminated through the circular polarizer 104 and the dual channel sensor in this embodiment. For example, the ambient light sensor 1081 and the ambient light sensor 1083 in the electronic device 10 can detect the change of the ambient light without being affected by the change of the image or the brightness of the display 102, so that the electronic device 10 can adjust the screen brightness more precisely.

In addition, a portion of the light emitted by the display 102 may be reflected in the electronic device 10 and detected by the optical sensor 1081 or the optical sensor 1083. Therefore, in some embodiments, the values of the intensity of the light detected by the optical sensor 1081 or the optical sensor 1083 may also be properly adjusted to optimize the intensity of the ambient light eventually obtained.

Other embodiments of the present invention will be detailed in the following. In order to simplify the illustration and clearly show the differences between various embodiments, the same components in the following would be labeled with the same symbol, the differences between various embodiments would be described in detail, and repeated features will not be described redundantly.

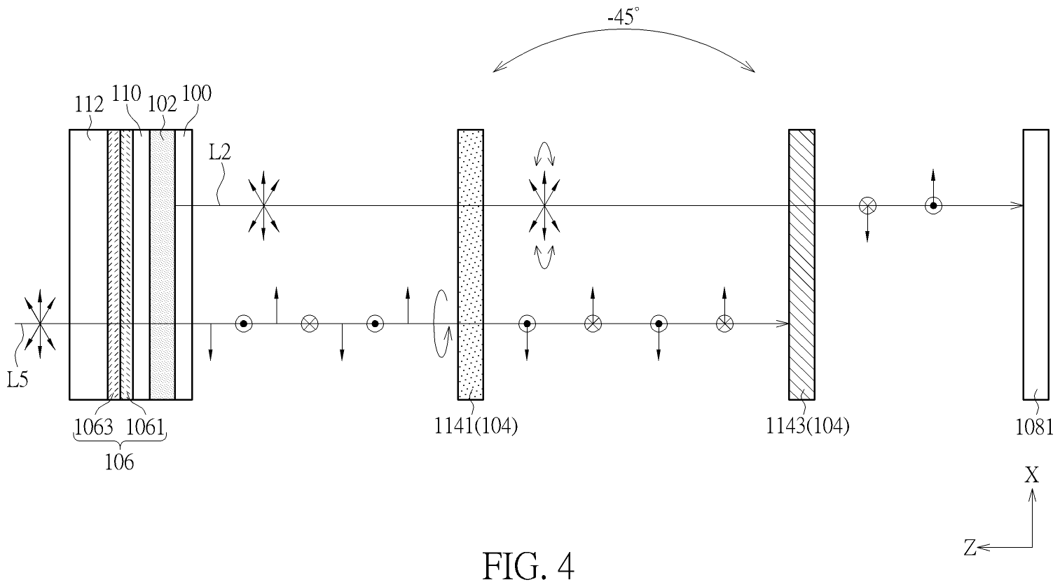

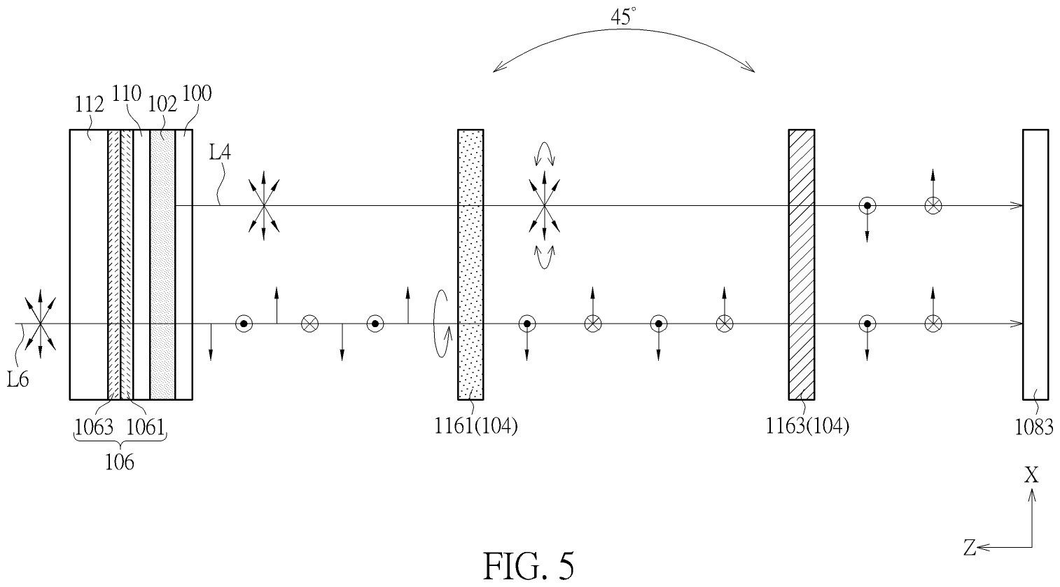

Please refer to FIG. 4 and FIG. 5. FIG. 4 is a schematic diagram of a first quarter waveplate, a first linear polarizer and a first optical sensor of a second embodiment according to the present invention. FIG. 5 is a schematic diagram of a second quarter waveplate, a second linear polarizer and a second optical sensor of the second embodiment according to the present invention. The difference between the second embodiment and the first embodiment is that the circular polarizer 106 of this embodiment may be a left-handed circular polarizer, but not limited herein. As shown in FIG. 4 and FIG. 5, when the ambient light L5 and the ambient light L6 enter the electronic device 10, the ambient light L5 and the ambient light L6 pass through the quarter waveplate 1061 and the linear polarizer 1063 of the circular polarizer 106 in sequence, and the ambient light L5 and the ambient light L6 can be left-handed polarized.

Since the included angle between the linear polarizer 1143 and the quarter waveplate 1141 is −45 degrees, the linear polarizer 1143 and the quarter waveplate 1141 may form a right-handed circular polarizer. As shown in FIG. 4, the ambient light L5 may pass through the quarter waveplate 1141 and the linear polarizer 1143 of the circular polarizer 104 in sequence. First, a portion of the polarization of the ambient light L5 perpendicular to the optical axis of the quarter waveplate 1141 is retarded by the influence of the crystalline structure of the quarter waveplate 1141 (e.g., the moving distance can be retarded by a length of a quarter of the wavelength) after the ambient light L5 passes through the quarter waveplate 1141, and thus the left-handed polarized ambient light L5 can become linearly polarized. However, since the polarization direction of the ambient light L5 passing through the quarter waveplate 1141 is perpendicular to the polarization direction of the linear polarizer 1143, the ambient light L5 is not able to pass through the linear polarizer 1143. Therefore, the optical sensor 1081 is not able to detect the ambient light L5.

As shown in FIG. 5, since the included angle between the linear polarizer 1163 and the quarter waveplate 1161 is 45 degrees, the linear polarizer 1163 and the quarter waveplate 1161 also form a left-handed circular polarizer. First, a portion of the polarization of the ambient light L6 perpendicular to the optical axis of the quarter waveplate 1161 is retarded by the influence of the crystalline structure of the quarter waveplate 1161 (e.g., the moving distance can be retarded by a length of a quarter of the wavelength) after the ambient light L6 passes through the quarter waveplate 1161, and thus the left-handed polarized ambient light L6 can become linearly polarized. Then, since the polarization direction of the ambient light L6 passing through the quarter waveplate 1161 may be parallel to the polarization direction of the linear polarizer 1163, the ambient light L6 may fully pass through the linear polarizer 1163. Therefore, the ambient light L6 can pass through the quarter waveplate 1161 and the linear polarizer 1163, and the ambient light L6 can be detected by the optical sensor 1083.

The light L2 or the light L4 may be similar to those in the first embodiment. The light L2 or the light L4 may have a first intensity before passing through the quarter waveplate 1141 or the quarter waveplate 1161. The light L2 may have a second intensity after passing through the quarter waveplate 1141 and the linear polarizer 1143, or the light L4 may have a second intensity after passing through the quarter waveplate 1161 and the linear polarizer 1163, and the second intensity is half of the first intensity.

Thus, the optical sensor 1081 can detect the light L2 of the display 102 with the second intensity but is not able to detect the ambient light L5, and the optical sensor 1083 can detect the light L4 of the display 102 with the second intensity and the ambient light L6 with the full intensity. Then, the full intensity of the ambient light L6 can be obtained by subtracting the values obtained by the optical sensor 1081 and the optical sensor 1083 through the calculation element.

Therefore, the full intensity of the ambient light L6 can be obtained and the interference of the light L2 and the light L4 emitted by the display 102 can be eliminated through the circular polarizer 104 and the dual channel sensor in this embodiment. For example, the ambient light sensor 1081 and the ambient light sensor 1083 in the electronic device 10 can detect the change of the ambient light without being affected by the change of the image or the brightness of the display 102, so that the electronic device 10 can adjust the screen brightness more precisely.

According to the embodiments described above, in the present invention, the right-handed circular polarizer (the quarter waveplate 1141 and the linear polarizer 1143) and the left-handed circular polarizer (the quarter waveplate 1161 and the linear polarizer 1163) are respectively disposed on the dual channel sensor (such as the optical sensor 1081 and the optical sensor 1083), thereby achieving the effect of fully detecting ambient light without being affected by the polarization direction of the circular polarizer 106 on the display. In addition, the circular polarizer 104 and the dual channel sensor of the present invention can achieve the filtering function at any angle pertaining to the circularly polarized light passing through the circular polarizer 106 and the display 102. Therefore, the circular polarizer 104 and the dual channel sensor of the present invention are not limited by specific placing angles, so that the circular polarizer 104 and the dual channel sensor have excellent product compatibility and can be compatible in displays having different structures.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electronic device, comprising:
a display comprising a first side and a second side opposite to the first side;
a first optical sensor and a second optical sensor disposed on the first side of the display; and
a first circular polarizer disposed on the first side of the display, wherein the first circular polarizer comprises:
a first quarter waveplate and a first linear polarizer, wherein the first quarter waveplate is disposed between the display and the first optical sensor, and the first linear polarizer is disposed between the first quarter waveplate and the first optical sensor; and
a second quarter waveplate and a second linear polarizer, wherein the second quarter waveplate is disposed between the display and the second optical sensor, and the second linear polarizer is disposed between the second quarter waveplate and the second optical sensor.

2. The electronic device according to claim 1, wherein the first quarter waveplate has an optical axis, the first linear polarizer has a polarization direction, and an included angle between the optical axis and the polarization direction is −45 degrees.

3. The electronic device according to claim 1, wherein the second quarter waveplate has an optical axis, the second linear polarizer has a polarization direction, and an included angle between the optical axis and the polarization direction is 45 degrees.

4. The electronic device according to claim 1, wherein when an ambient light enters the electronic device, the ambient light passes through the first quarter waveplate and the first linear polarizer, and the ambient light is detected by the first optical sensor.

5. The electronic device according to claim 1, wherein when an ambient light enters the electronic device, the ambient light passes through the second quarter waveplate, but the ambient light is not able to pass through the second linear polarizer.

6. The electronic device according to claim 1, wherein the display emits a light, the light has a first intensity before passing through the first quarter waveplate or the second quarter waveplate, the light has a second intensity after passing through the first quarter waveplate and the first linear polarizer or after passing through the second quarter waveplate and the second linear polarizer, and the second intensity is half of the first intensity.

7. The electronic device according to claim 1, wherein an area of the first quarter waveplate is the same as an area of the first optical sensor, and an area of the second quarter waveplate is the same as an area of the second optical sensor.

8. The electronic device according to claim 1, wherein an area of the first linear polarizer is the same as an area of the first optical sensor, and an area of the second linear polarizer is the same as an area of the second optical sensor.

9. The electronic device according to claim 1, further comprising a second circular polarizer disposed on the second side of the display, wherein the second circular polarizer comprises a third quarter waveplate and a third linear polarizer, and the third quarter waveplate is disposed between the third linear polarizer and the display.

10. The electronic device according to claim 1, further comprising a cover layer disposed on the second side of the display.
